(19) United States
(12) Patent Application Publication
(10) Pub. No.: US 2025/0389591 A1
(43) Pub. Date: Dec. 25, 2025

(54) MEMORY DEVICES WITH PYROELECTRIC MATERIAL LAYER

(71) Applicant: Inte Corporation, Santa Clara, CA (US)

(72) Inventors: Abhishek A. Sharma, Portland, OR (US); Wilfred Gomes, Portland, OR (US); Anand S. Murthy, Portland, OR (US); Sagar Suthram, Portland, OR (US); Tahir Ghani, Portland, OR (US); Pushkar Sharad Ranade, San Jose, CA (US)

(73) Assignee: Intel Corporation, Santa Clara, CA (US)

(21) Appl. No.: 18/748,162

(22) Filed: Jun. 20, 2024

(51) Int. Cl. G01J 5/34; H10B 80/00; H10N 30/85

(52) U.S. Cl. CPC G01J 5/34; H10B 80/00; H10N 30/85

(57) ABSTRACT

Memory devices that include a pyroelectric layer between two metal layers. The pyroelectric layer may have a crystal configuration that is temperature-dependent. Different crystal configurations have different degrees of polarization. A higher temperature causes a pyroelectric material to have an orthorhombic crystal structure, which has a lesser degree of polarization, leading to lower power consumption and lower leakage. A lower temperature causes the pyroelectric material to have a tetragonal crystal structure, which has a higher degree of polarization, leading to higher power consumption, along with faster switching speed and better memory retention.

### BACKGROUND

Embedded memory is important to the performance of modern system-on-a-chip (SoC) technology. Low power and high-density embedded memory is used in many different computer products, and further improvements are always desirable. In certain applications, it is useful for memory cells to operate across a wide range of temperatures. For example, processing circuity coupled to memory cells can generate a large amount of heat, which requires embedded memory to operate at high temperatures.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is an electrical circuit diagram of a memory cell, according to some embodiments of the present disclosure.

FIG. 2 is a cross-section of an example memory cell with a transistor and a capacitor with a pyroelectric layer, according to some embodiments of the present disclosure.

FIGS. 3A and 3B illustrate different crystal structures of pyroelectric materials, according to some embodiments of the present disclosure.

FIG. 4 is an electrical circuit diagram of a first array of memory cells, according to some embodiments of the present disclosure.

FIG. 5 is an electrical circuit diagram of a second array of memory cells, according to some embodiments of the present disclosure.

FIG. 6 is a cross-section of an example one-transistor memory cell with a pyroelectric layer, according to some embodiments of the present disclosure.

FIG. 7 is a cross-section of an example set of memory cells with one transistor coupled to multiple capacitors, with a pyroelectric layer in each capacitor, according to some embodiments of the present disclosure.

FIGS. 8A and 8B are top views of a wafer and dies that include memory cells with pyroelectric layers in accordance with any of the embodiments disclosed herein.

FIG. 9 is a cross-sectional side view of an IC device that may include one or more memory cells with pyroelectric layers in accordance with any of the embodiments disclosed herein.

FIG. 10 is a cross-sectional side view of an IC device assembly that may include one or more memory cells with pyroelectric layers in accordance with any of the embodiments disclosed herein.

FIG. 11 is a block diagram of an example computing device that may include one or more memory cells with pyroelectric layers in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Memory cells that include a pyroelectric material are described herein. Pyroelectrics are a class of polar crystals that exhibit a coupling between electrical polarization and temperature, such that a change in temperature results in a change in the electric dipole moment, i.e., a change in the overall polarity of the material. For example, at a high temperature, the crystal structure leads to a lower amount of polarization within the material; at a low temperature, the crystal structure leads to a higher degree of polarization within the material.

The pyroelectric material's polarization state may be used to store a bit. For example, a “logic state” of one of the pyroelectric memory cells disclosed herein may refer to one of a finite number of states that the cell can have, e.g. logic states “1” and “0,” where each state is represented by a different polarization of the pyroelectric material of the cell. Applying an electric field to the pyroelectric material may change the polarization state of the material. The pyroelectric material is hysteretic, meaning that its state (in this case, polarization state) depends on the history of the material (e.g., on a previous polarization state of the material). The pyroelectric memory cells described herein exhibit spontaneous electric polarization, i.e., displacement of positive and negative charges from their original position, where the polarization can be reversed or reoriented by applying an electric field to the pyroelectric material. The pyroelectric memory cells and, in particular, the pyroelectric material may exhibit two different polarization states, corresponding to “1” and “0,” for example. The displacement of the charges (i.e., the polarization state) may be maintained for some time, even in the absence of an electric field. In this respect, the pyroelectric memory cell may be similar to a ferroelectric memory cell. However, unlike typical ferroelectric memory cells, the crystal structure of the pyroelectric material changes at different temperatures, leading to different degrees of polarization in the different crystal structures.

When used as the storage layer in a memory device (e.g., as the material between two plates in a storage capacitor), the degree of polarization is related to the amount of power consumption of the memory device, as well as performance factors, such as switching speed and retention. For example, a higher temperature causes a pyroelectric material to have an orthorhombic crystal structure, while a lower temperature causes the pyroelectric material to have a tetragonal crystal structure. The higher-temperature orthorhombic material has a lesser degree of polarization, which leads to lower power consumption and lower leakage. The lower-temperature tetragonal material has a higher degree of polarization, which may lead to higher power consumption, along with faster switching speed and better memory retention (e.g., retention of a particular polarization state).

For many memory applications, the lower-temperature operation characteristics (high retention, fast switching) are superior. However, when used in combination with other heat-generating circuitry, it is beneficial for the memory cells to operate in a lower-power state at high temperatures. The low-power operations in the orthorhombic configuration generate less heat than the higher-power operations in the tetragonal configuration, and thus, the memory cells described herein can help prevent system-wide overheating when operating at relatively high temperatures by automatically switching to the orthorhombic crystal configuration. The transition temperature (i.e., the temperature at which the pyroelectric material transitions between the tetragonal configuration and orthogonal configuration) depends on the pyroelectric material selected, and dopants added to the pyroelectric material may adjust the transition temperature or other properties of the pyroelectric material.

Different configurations of memory cells that include pyroelectric materials or a pyroelectric layer are described herein. For example, a memory cell may include a capacitor for storing a bit value or a memory state (e.g., logical “1” or “0”) of the cell, and an access transistor controlling access to the cell (e.g., access to write information to the cell or access to read information from the cell). Such a memory cell may be referred to as a “1T-1C memory cell,” highlighting the fact that it uses one transistor (i.e., “1T” in the term “1T-1C memory cell”) and one capacitor (i.e., “1C” in the term “1T-1C memory cell”). The capacitor of a 1T-1C memory cell may be coupled to one source or drain (S/D) region/terminal of the access transistor (e.g., to the source region of the access transistor) by a first S/D contact, while the other S/D region of the access transistor may be coupled to a bitline (BL) by a second S/D contact, and a gate terminal of the transistor may be coupled to a word line (WL) by a gate contact. Various 1T-1C memory cells have, conventionally, been implemented with access transistors being front end of line (FEOL), logic-process based, transistors implemented in an upper-most layer of a semiconductor substrate.

The BL and WL are each formed from metal interconnects that are coupled to additional memory cells, and in particular, access transistors of other memory cells. For example, a BL runs along a column of memory cells, and the BL is coupled to one S/D terminal of each of the access transistors in the column of memory cells via an S/D contact. A WL runs along a row of memory cells, and the WL is coupled to the gate of each of the access transistors in the row of memory cells via a gate contact.

In certain embodiments disclosed herein, a memory array includes multiple capacitors coupled to a single access transistor. For example, the memory architecture may have multiple active memory layers, realizing a vertically-stacked memory array. An individual one of multiple pyroelectric capacitors coupled to an access transistor may store a memory state, thus realizing a memory cell of a memory array. An example memory unit of an IC device implementing memory with one access transistor for multiple pyroelectric capacitors includes an access transistor and N pyroelectric capacitors coupled to the access transistor in a way that allows selecting all or all of the N hysteretic capacitors for performing READ and/or WRITE operation when the access transistor is ON (e.g., when current may be conducted between source and drain terminals of the access transistor). Such arrangements may be referred to as 1T-nC memory cells.

In other embodiments disclosed herein, the pyroelectric layer is included in the transistor itself, so that the transistor acts as a storage unit; a separate capacitor is not included in the memory cell. Memory cells formed from a single transistor are referred to as 1T memory cells. In these technologies, the memory cell consists of a single transistor that changes its properties to store data. As disclosed herein, the polarization of a pyroelectric material within the transistor changes to represent information, e.g., a “1” or a “0”. The polarization may be detected through a change in threshold voltage, or a change in resistance, of the transistor. 1T memory arrangements provide high scalability and greater density than arrangements that include a capacitor, and may provide faster speeds and higher durability than other arrangements.

The memory cells with pyroelectric layers described herein may be implemented in, or in combination with, more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g. logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

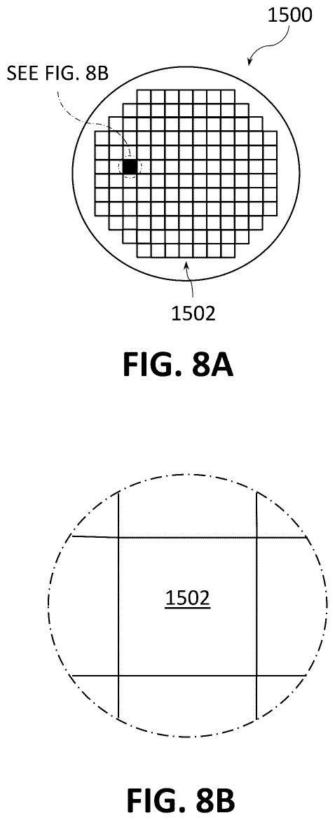

For convenience, if a collection of drawings designated with different letters are present, e.g., FIGS. 8A-8B, such a collection may be referred to herein without the letters, e.g., as “FIG. 8.”

### Example 1T-1C Memory Cell With Pyroelectric Capacitor

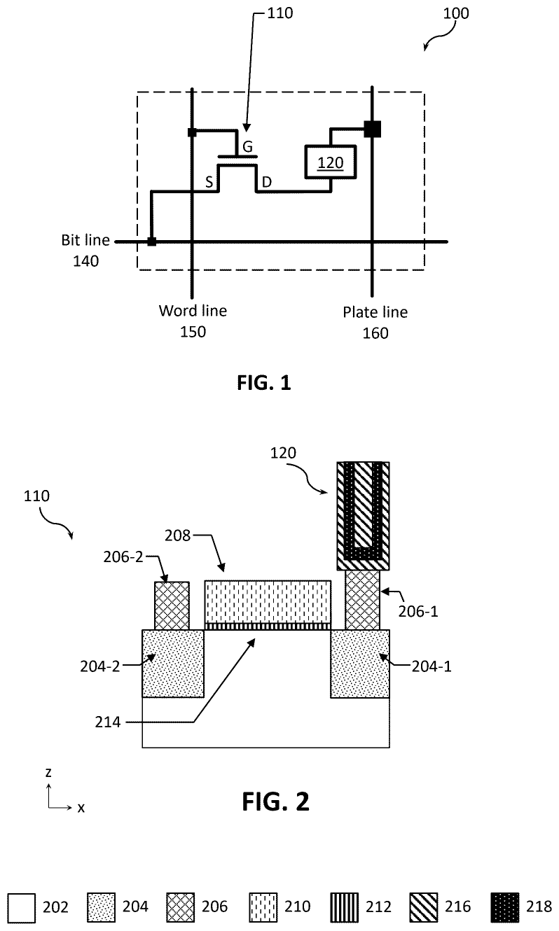

FIG. 1 is a circuit diagram of a memory cell, according to some embodiments of the present disclosure. In particular, FIG. 1 is an electrical circuit diagram of an example 1T-1C memory cell 100. The memory cell 100 may be a pyroelectric memory cell, i.e., a memory cell that include a pyroelectric material as a storage medium. As shown, the 1T-1C cell 100 may include an access transistor 110 and a capacitor 120. The capacitor 120 may include a layer of pyroelectric material. The access transistor 110 has a gate terminal, a source terminal, and a drain terminal, indicated in the example of FIG. 1 as terminals G, S, and D, respectively. In the following, the terms “terminal” and “electrode” may be used interchangeably. Furthermore, for S/D terminals, the terms “terminal” and “region” may be used interchangeably.

As shown in FIG. 1, in the 1T-1C cell 100, the gate terminal of the access transistor 110 may be coupled to a word line (WL) 150, one of the S/D terminals of the access transistor 110 may be coupled to a bit line (BL) 140, and the other one of the S/D terminals of the access transistor 110 may be coupled to a first electrode of the capacitor 120. As also shown in FIG. 1, the other electrode of the capacitor 120 may be coupled to a capacitor plate line (PL) 160. As is known in the art, WL, BL, and PL may be used together to read and program the capacitor 120.

Each of the BL 140, the WL 150, and the PL 160, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

FIG. 2 is a cross-section of an example memory cell with a transistor and a pyroelectric capacitor, according to some embodiments of the present disclosure. FIG. 2 illustrates how a transistor (e.g., the transistor 110) and a capacitor (e.g., the capacitor 120) may be used to form a 1T-1C memory cell. A number of elements referred to in the description of FIGS. 2, 6, and 7 with reference numerals are illustrated in these figures with different patterns, with a legend showing the correspondence between the reference numerals and patterns being provided at the bottom or side of each drawing page containing FIGS. 2, 6, and 7. For example, the legend under FIG. 2 illustrates that this figure uses different patterns to show a channel material 202, S/D regions 204, contacts 206, a gate electrode 210, a gate dielectric 212, a capacitor electrode 216, and a pyroelectric material 218.

In the drawings, some example structures of various devices and assemblies described herein are shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

In general, implementations of the present disclosure may be formed or carried out on a support structure. The support structure may be, e.g., a substrate, a die, a wafer or a chip. For example, the support structure may be the wafer 1500 of FIG. 8A, discussed below, and may be, or be included in, a die, e.g., the singulated die 1502 of FIG. 8B, discussed below. The support structure extends along the x-y plane in the coordinate system shown in FIG. 2. In some embodiments, a support structure may be used during a fabrication process and later removed. In some embodiments, the channel material 202 is over the support structure. In other embodiments, the channel material 202 is a portion of the support structure, e.g., an upper portion of the support structure.

In some embodiments, the support structure may be a substrate that includes silicon and/or hafnium. More generally, the support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the substrate may be formed are described here, any material that may serve as a foundation upon which a semiconductor device including one or more nanoribbon transistors, as described herein, may be built falls within the spirit and scope of the present disclosure.

In general, a field-effect transistor (FET), e.g., a metal oxide semiconductor (MOS) FET (MOSFET), is a three-terminal device that includes source, drain, and gate terminals and uses electric field to control current flowing through the device. A FET typically includes a channel material, a source region and a drain region provided in the channel material, and a gate stack that includes a gate electrode material, alternatively referred to as a “work function” material, provided over a portion of the channel material between the source and the drain regions, and, optionally, also includes a gate dielectric material between the gate electrode material and the channel material. This general structure of an example of the transistor 110 is shown in FIG. 2, which shows the channel material 202, S/D regions 204 (shown as a first S/D region 204-1, e.g., a source region, and a second S/D region 204-2, e.g., a drain region), contacts 206 to the S/D regions (shown as a first S/D contact 206-1, providing electrical contact to the first S/D region 204-1, and a second S/D contact 206-2, providing electrical contact to the second S/D region 204-2), and a gate stack 208, which includes at least a gate electrode 210 and may also, optionally, include a gate dielectric 212.

The channel material 202 may include a monocrystalline semiconductor, such as silicon (Si) or germanium (Ge). In some embodiments, the channel material 202 may include a compound semiconductor with a first sub-lattice of at least one element from group III of the periodic table (e.g., Al, Ga, In), and a second sub-lattice of at least one element of group V of the periodic table (e.g., P, As, Sb). For some embodiments, the channel material 202 may include a III-V material having a high electron mobility, such as, but not limited to InGaAs, InP, InSb, and InAs. For some such embodiments, the channel material 202 may be a ternary III-V alloy, such as InGaAs, GaAsSb, InAsP, or InPSb. For some InₓGa₁₋ₓAs embodiments, the In content (x) may be between 0.6 and 0.9, and may advantageously be at least 0.7 (e.g., In_{0.7}Ga_{0.3}As). For other embodiments, one or more of the semiconductor materials may be a group IV material having a high hole mobility, such as, but not limited to Ge or a Ge-rich SiGe alloy. For some example embodiments, the channel material 202 may have a Ge content between 0.6 and 0.9, and may be at least 0.7.

In some embodiments, the channel material 202 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the channel material 202 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus. Suitable dopants for the channel material 202 may include gallium, indium, aluminum, fluorine, boron, phosphorus, arsenic, nitrogen, tantalum, tungsten, magnesium, etc.

As shown in FIG. 2, a first and a second S/D regions 204-1, 204-2 (together referred to as “S/D regions 204”) may be included on either side of the gate stack 208, thus realizing a transistor. As is known in the art, source and drain regions (also sometimes interchangeably referred to as “diffusion regions”) are formed for the gate stack of a FET. In some embodiments, the S/D regions 204 of the transistor 110 may be regions of doped semiconductors, e.g. regions of the channel material 202 (e.g., of the channel portion 214) doped with a suitable dopant to a suitable dopant concentration, so as to supply charge carriers for the transistor channel. In some embodiments, the S/D regions 204 may be highly doped, e.g. with dopant concentrations of about 1·10²¹ cm⁻³, in order to advantageously form Ohmic contacts with the respective S/D contacts 206, although, in other embodiments, these regions may also have lower dopant concentrations and may form Schottky contacts in some implementations. Irrespective of the exact doping levels, the S/D regions 204 may be the regions having dopant concentration higher than in other regions, e.g. higher than a dopant concentration in a region of the channel material 202 between the first S/D region 204-1 and the second S/D region 204-2, and, therefore, may be referred to as “highly doped” (HD) regions. In some embodiments, the S/D regions 204 may generally be formed using either an implantation/diffusion process or an etching/deposition process. In the former process, dopants such as boron, aluminum, antimony, phosphorous, or arsenic may be ion-implanted into the one or more semiconductor materials of the upper portion of the channel material 202 to form the S/D regions 204. An annealing process that activates the dopants and causes them to diffuse further into the channel material 202 may follow the ion implantation process. In the latter process, the one or more semiconductor materials of the channel material 202 may first be etched to form recesses at the locations for the future S/D regions. An epitaxial deposition process may then be carried out to fill the recesses with material (which may include a combination of different materials) that is used to fabricate the S/D regions 204. In some implementations, the S/D regions 204 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 204 may be formed using one or more alternate semiconductor materials such as germanium or a group III-V material or alloy. Although FIG. 2 illustrates the first and second S/D regions 204 with a single pattern, suggesting that the material composition of the first and second S/D regions 204 is the same, this may not be the case in some other embodiments of the transistor 110. Thus, in some embodiments, the material composition of the first S/D region 204-1 may be different from the material composition of the second S/D region 204-2.

As further shown in FIG. 2, S/D contacts 206-1 and 206-2 (together referred to as “S/D contacts 206”), formed of one or more electrically conductive materials, may be used for providing electrical connectivity to the S/D regions 204-1 and 204-2, respectively. In various embodiments, one or more layers of metal and/or metal alloys may be used to form the S/D contacts 206. For example, the electrically conductive materials of the S/D contacts 206 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the S/D contacts 206 may include one or more electrically conductive alloys, oxides, or carbides of one or more metals. In some embodiments, the S/D contacts 206 may include a doped semiconductor, such as silicon or another semiconductor doped with an N-type dopant or a P-type dopant. Metals may provide higher conductivity, while doped semiconductors may be easier to pattern during fabrication. Although FIG. 2 illustrates the first and second S/D contacts 206 with a single pattern, suggesting that the material composition of the first and second S/D contacts 206 is the same, this may not be the case in some other embodiments of the transistor 110. Thus, in some embodiments, the material composition of the first S/D contact 206-1 may be different from the material composition of the second S/D contact 206-2.

Turning to the gate stack 208, the gate electrode 210 may include at least one P-type work function metal or N-type work function metal, depending on whether the transistor 110 is a PMOS transistor or an NMOS transistor. For a PMOS transistor, metals that may be used for the gate electrode 210 may include, but are not limited to, ruthenium, palladium, platinum, cobalt, nickel, and conductive metal oxides (e.g., ruthenium oxide). For an NMOS transistor, metals that may be used for the gate electrode 210 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 210 may include a stack of two or more metal layers, where one or more metal layers are WF metal layers and at least one metal layer is a fill metal layer. Further metal layers may be included for other purposes, such as to act as a diffusion barrier layer.

If used, the gate dielectric 212 may at least laterally surround the channel portion 214, and the gate electrode 210 may laterally surround the gate dielectric 212 such that the gate dielectric 212 is disposed between the gate electrode 210 and the channel material 202. In various embodiments, the gate dielectric 212 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 212 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 212 during manufacture of the transistor to improve the quality of the gate dielectric 212. In some embodiments, the gate dielectric 212 may have a thickness between about 0.5 nanometers and 3 nanometers, including all values and ranges therein, e.g., between about 1 and 3 nanometers, or between about 1 and 2 nanometers.

In some embodiments, the gate stack 208 may be surrounded by a dielectric spacer, not specifically shown in FIG. 2. The dielectric spacer may be configured to provide separation between the gate stacks 208 of different transistors which may be provided adjacent to one another (e.g., different transistors provided along a single fin if the transistors are FinFETs), as well as between the gate stack 208 and one of the S/D contacts 206 that is disposed on the same side as the gate stack 208. Such a dielectric spacer may include one or more low-k dielectric materials. Examples of the low-k dielectric materials that may be used as the dielectric spacer (or in other dielectric materials described herein) include, but are not limited to, silicon dioxide, carbon-doped oxide, silicon nitride, fused silica glass (FSG), and organosilicates such as silsesquioxane, siloxane, and organosilicate glass. Other examples of low-k dielectric materials include organic polymers such as polyimide, polynorbornenes, benzocyclobutene, perfluorocyclobutane, or polytetrafluoroethylene (PTFE). Still other examples of low-k dielectric materials that may be used as the dielectric spacer include silicon-based polymeric dielectrics such as hydrogen silsesquioxane (HSQ) and methylsilsesquioxane (MSQ). Other examples of low-k materials that may be used in a dielectric spacer include various porous dielectric materials, such as for example porous silicon dioxide or porous carbon-doped silicon dioxide, where large voids or pores are created in a dielectric in order to reduce the overall dielectric constant of the layer, since voids can have a dielectric constant of nearly 1.

In this example, both of the S/D contacts 206 are on the same side of the transistor, e.g., a front side of the transistor. The gate stack 208 is also on the front side of the transistor. In other embodiments, one or more of the S/D contacts 206, and/or the gate stack 208, are on a back side of the transistor, referred to as the back side.

Transistors, such as access transistors for memory cells, may be implemented using any suitable transistor architecture, e.g. planar or non-planar architectures. For example, an access transistor may be implemented as a FinFET or a nanoribbon transistor, as are known in the art. In some embodiments, the gate stack 208 may be recessed relative to the S/D contacts 206, so that a height of the channel material 202 under the gate stack 208 is less than a height of the channel material 202 under the S/D regions 204, or a height of the channel material 202 under the gate stack 208 is less than a height of the channel material 202 under the S/D regions 204 plus the height of the S/D regions 204.

The capacitor 120 is illustrated as a three-dimensional capacitor that includes a layer of the pyroelectric material 218. The capacitor 120 can store a bit value, or a memory state (e.g., logical “1” or “0”) of the memory cell 100, and the transistor 110 may then function as an access transistor controlling access to the memory cell 100 (e.g., access to write information to the cell or access to read information from the cell). By coupling the capacitor 120 to the S/D region 204-1, the capacitor 120 is configured to store the memory state of the memory cell 100. In some embodiments, the capacitor 120 may be coupled to the S/D region 204-1 via a storage node (not specifically shown in FIG. 2) coupled to the S/D region 204-1. In some embodiments, the S/D contact 206-1 may be considered to be the storage node.

The capacitor 120 includes a first electrode 216-1 that is over and in contact with the S/D contact 206-1. The first electrode 216-1 may be a layer of a conductive material that is formed within a dielectric material, e.g., within an opening in a dielectric material. A layer of the pyroelectric material 218 is deposited over the first electrode 216-1 and nested within the first electrode 216-1. A second electrode 216-2 is deposited over the pyroelectric material 218 and nested within the pyroelectric material 218. In this embodiment, the second electrode 216-2, which is nested within the first electrode 216-1 and the pyroelectric material 218, completely fills an opening within the pyroelectric material 218, rather than having a further opening within the second electrode 216-2. In alternate embodiments, a further layer of dielectric is nested within the second electrode 216-2.

The first electrode 216-1 and second electrode 216-2 may include any suitable electrically conductive material, which may include a metal, an alloy, or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals. The electrodes 216 may generally be referred to as metal layers, e.g., the first electrode 216-1 and second electrode 216-2 form a pair of metal layers with the pyroelectric material 218 between them.

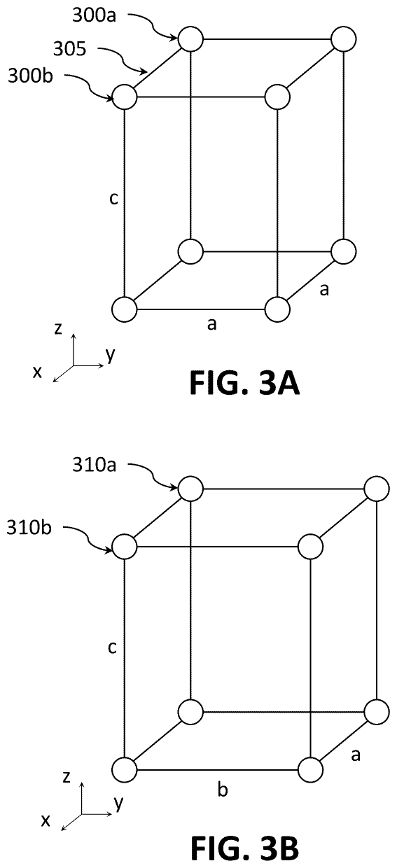

The pyroelectric material 218 is a crystalline material in which the crystal structure is temperature-dependent. The pyroelectric material 218 may have alternatively an orthorhombic or tetragonal crystal structure. Example crystal structures are illustrated in FIGS. 3A and 3B, described below. The temperature range associated with the different crystal structures depends on the material. In general, for a given pyroelectric material, a first temperature range associated with the orthorhombic structure is above a second temperature range associated with the tetragonal structure. As one example, hafnium oxide has a tetragonal crystal structure and a relatively high degree of polarization below around 550° C. (e.g., between −100° C. and 575° C.), and an orthorhombic crystal structure and relatively low degree of polarization over around 600° C. (e.g., between 575° C. and 800° C.). Doping the hafnium oxide may alter the temperature ranges, e.g., to lower the temperature at which the crystal transitions between orthorhombic and tetragonal. For example, doping hafnium oxide with silicon can reduce the temperature at which the material switches between orthorhombic and tetragonal. Different amounts of silicon dopant may result in different transition temperatures, e.g., a higher concentration of silicon dopant may lead to a lower switching temperature.

The pyroelectric material 218 is also a ferroelectric material, i.e., a material that has two non-zero spontaneous polarization states that can be reversed by application of an external electrical field. As described above, the degree of polarization varies based on the crystal structure, and thus, varies with temperature.

Suitable pyroelectric materials 218 include certain oxide semiconductors, e.g., oxygen combined with zinc (i.e., zinc oxide) or indium (i.e., indium oxide); or nitrogen combined with aluminum (aluminum nitride), zirconium (zirconium nitride), or hafnium (hafnium nitride). Other suitable materials include PZT (lead zirconium titanate, which includes lead, zirconium, titanium, and oxygen); BTO (barium titanate, which includes barium, titanium, and oxygen); tantalum oxide (which includes tantalum and oxygen). In other embodiments, the pyroelectric material 218 may include hafnium oxide (which includes hafnium and oxygen) or zirconium oxide (which includes zirconium and oxygen); hafnium oxide or zirconium oxide may optionally be doped with vacancies (i.e., vacancies in the hafnium or zirconium positions) and/or one or more of zirconium, hafnium, silicon, aluminum, tantalum, germanium, gallium, titanium, or another dopant. In other embodiments, different highly polar oxides or nitrides not specifically mentioned above may be used as the pyroelectric material 218. In some embodiments, a mixture of different materials may be included in the pyroelectric material 218, e.g., hafnium oxide mixed with one or more of silicon oxide, scandium oxide, aluminum oxide, gallium nitride, indium nitride, indium oxide, tantalum oxide, aluminum nitride, aluminum scandium nitride, etc.

The crystal structure may be highly consistent across the pyroelectric material 218. For example, the pyroelectric material 218 may also be capable of forming different crystal structures, e.g., cubic or hexagonal structures, which are not suitable for use as a memory device. The pyroelectric material 218 (e.g., one or more cross-sections through the pyroelectric material 218) may include a minimal amount, e.g., less than 5%, less than 2%, less than 1%, less than 0.5%, of crystals in an undesired configuration, e.g., cubic or hexagonal. Said another way, in a cross-section through the pyroelectric material 218, at least 95%, at least 98%, at least 99%, or at least 99.5% of the pyroelectric material 218 may have an orthorhombic or tetragonal crystal structure. Whether the pyroelectric material 218 is orthorhombic or tetragonal depends on temperature, as described above. The desired crystal structures (orthorhombic and tetragonal) may be achieved by controlling deposition temperature; a higher deposition temperature (e.g., at least 250° C. or at least 300° C.) may provide the desired crystal structure. The deposition temperature may be compatible for back-end processing, e.g., the deposition temperature may be in a range of 250-400° C. In other embodiments, if the pyroelectric material 218 is deposited during front end processing, a higher deposition temperature may be used (e.g., above 400° C.).

The capacitor 120 may additionally include one or more additional materials not specifically shown in FIG. 2. For example, the capacitor 120 may include a dielectric layer between the pair of electrodes 216-1 and 216-2, e.g., between the first electrode 216-1 and the pyroelectric material 218 and/or between the pyroelectric material 218 and the second electrode 216-2.

Although not specifically shown in FIG. 2, the memory cell 100 may further include a bitline to transfer the memory state and coupled to the one of the S/D regions 204 to which the capacitor 120 is not coupled (e.g., to the S/D region 204-2, for the illustration of FIG. 2). Such a bitline can be connected to a sense amplifier and a bitline driver which may, e.g., be provided in a memory peripheral circuit associated with a memory array in which the memory cell 100 may be included. Furthermore, although also not specifically shown in FIG. 2, the memory cell 100 may further include a wordline, coupled to the gate terminal of the transistor, e.g., coupled to the gate stack 208, to supply a gate signal. The transistor may be configured to control transfer of a memory state of the memory cell 100 between the bitline and the storage node or the capacitor 120 in response to the gate signal. The capacitor 120, and in particular, the second electrode 216-2 of the capacitor 120, may be coupled to a plateline, as shown in FIG. 1.

### Example Crystal Structures of Pyroelectric Materials

FIG. 3A and 3B illustrate two example crystal structures of pyroelectric materials, according to some embodiments of the present disclosure. A pyroelectric material may alternate between the crystal structures represented in FIG. 3A and FIG. 3B, and the different structures may be associated with different degrees of polarizations. FIG. 3A illustrates a tetragonal crystal structure. In this structure, atoms are represented as dots, e.g., 300a and 300b. The atoms are positioned the corners of the crystal, and edges representing lengths between various pairs of atoms are shown. For example, the edge 305 extends between the atoms 300a and 300b. In general, a crystal structure of a pyroelectric material can be described by six lattice parameters: three representing the edge lengths, and three representing the angles between the cell edges. In the tetragonal and orthorhombic structures described herein, all of the angles are 90°. In a tetragonal structure, two of the edge lengths are equal, and one of the edge lengths is different. For example, in the reference coordinate system shown in FIG. 3A, the edge lengths in the x-direction and the y-direction both have a length a. Thus, the base and top of the depicted crystal each form a square. The edge length in the z-direction is c, which is different from the length a. The crystal has the shape of a rectangular prism with a square base.

FIG. 3B illustrates an orthorhombic crystal structure. Atoms in this crystal structure, represented as dots 310 (e.g., dots 310a and 310b), are positioned at the corners of the crystal, and edges representing lengths between certain pairs of atoms are shown. In an orthorhombic crystal structure, the angles between the cell edges are all 90°, but the edge lengths are all different. For example, in the reference coordinate system shown in FIG. 3B, the edge length in the x-direction is a, the edge length in the y-direction is b, and the edge length in the z-direction is c, where a≠b≠c.

### Example Array of 1T-1C Memory Cells

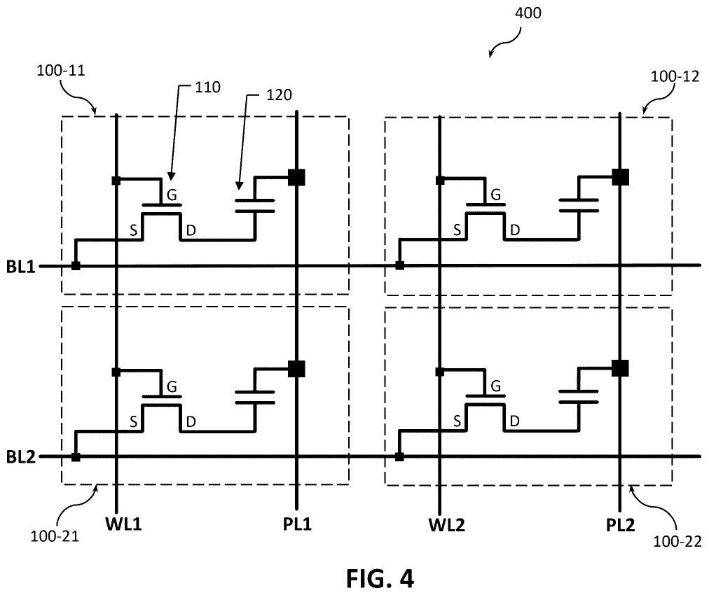

FIG. 4 is an electrical circuit diagram of a first array of memory cells, according to some embodiments of the present disclosure. FIG. 4 provides a schematic illustration of a plurality of the 1T-1C memory cells 100 (here, four cells) illustrated in FIGS. 1 and 2, arranged in an array 400. Each 1T-1C memory cell 100 is illustrated in FIG. 4 to be within a dashed box labeled 100-11, 100-12, 100-21, and 100-22. Each 1T-1C memory cell 100 includes an access transistor 110 and a capacitor 120, as described above.

The 1T-1C memory cells each have a gate terminal, a source terminal, and a drain terminal, indicated as terminals G, S, and D, respectively. As described with respect to FIG. 1, in each 1T-1C memory cell 100, the gate terminal of the access transistor 110 is coupled to a WL, one of the source or drain terminals of the access transistor 110 is coupled to a BL, and the other one of the source or drain terminals of the access transistor 110 is coupled to a first electrode of the capacitor 120. The other electrode of the capacitor 120 is coupled to a PL.

While the array 400 shown in FIG. 4 has four such memory cells 100, in other embodiments, the array 400 may, and typically would, include many more memory cells. Furthermore, in other embodiments, the 1T-1C memory cells as described herein may be arranged in arrays in other manners as known in the art, all of which being within the scope of the present disclosure.

FIG. 4 illustrates that BL can be shared among multiple memory cells 100 in a column, and that WL and PL can be shared among multiple memory cells 100 in a row. As is conventionally used in context of memory, the terms “row” and “column” do not reflect the, respectively, horizontal and vertical orientation on a page of a drawing illustrating a memory array but, instead, reflect on how individual memory cells are addressed. Namely, memory cells 100 sharing a single BL are said to be in the same column, while memory cells 100 sharing a single WL are said to be on the same row. Thus, in FIG. 4, the horizontal lines refer to columns while vertical lines refer to rows. Different instances of each line (BL, WL, and PL) are indicated in FIG. 4 with different reference numerals, e.g. BL1 and BL2 are the two different instances of the BL as described herein. The same reference numeral on the different lines WL and PL indicates that those lines are used to address/control the memory cells in a single row, e.g. WL1 and PL1 are used to address/control the memory cells 100 in row 1, and so on. Each memory cell 100 may then be addressed by using the BL corresponding to the column of the cell and by using the WL and PL corresponding to the row of the cell. For example, the memory cell 100-11 is controlled by BL1, WL1, and PL1, the memory cell 100-12 is controlled by BL1, WL2, and PL2, and so on.

### Example Array of 1T Memory Cells

The pyroelectric material may be included in different forms of memory devices besides the 1T-1C memory cells described with respect to FIGS. 1-4. For example, a pyroelectric layer may be included directly in the transistor, so that the transistor itself is a storage unit, and a separate capacitor is not needed.

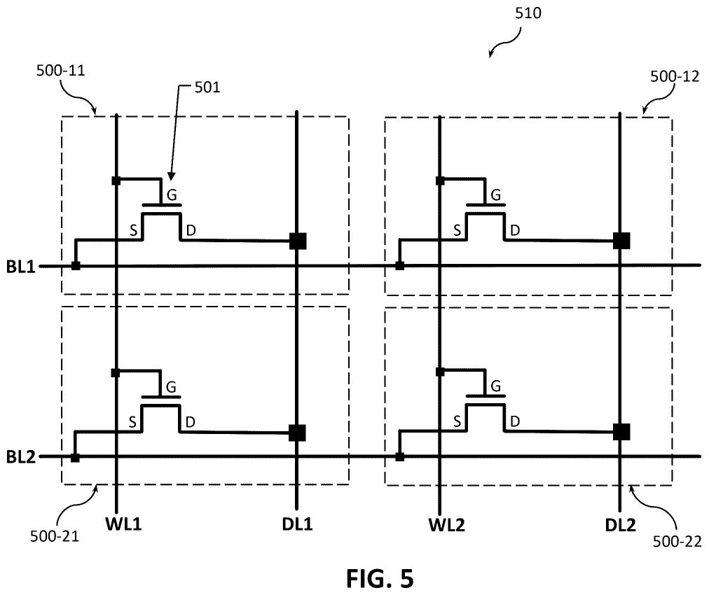

FIG. 5 is an electrical circuit diagram of a second array of memory cells, according to some embodiments of the present disclosure. FIG. 5 illustrates 1T memory cells that do not have a capacitor, and instead include the pyroelectric material as a layer in the transistor, e.g., in a layer between the gate electrode and the semiconductor channel.

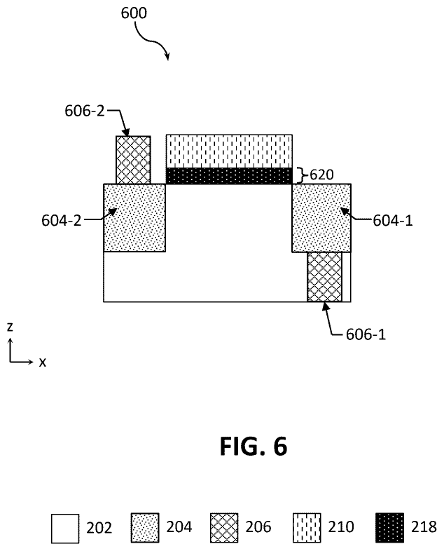

More specifically, FIG. 5 provides a schematic illustration of a plurality of the 1T memory cells 500 (here, four cells), arranged in an array 510. Each 1T memory cell 500 is illustrated in FIG. 5 to be within a dashed box labeled 500-11, 500-12, 500-21, and 500-22. Each 1T memory cell 500 is a transistor that includes a pyroelectric layer; an example cross-section through a 1T memory cell 500 is illustrated in FIG. 6, described below.

The 1T memory cells each have a gate terminal, a source terminal, and a drain terminal, indicated as terminals G, S, and D, respectively. Similar to the memory cell 100 in FIG. 1, in each 1T memory cell 500, the gate terminal of the transistor is coupled to a WL, and one of the source or drain terminals of the transistor is coupled to a BL. In this example, rather than the other one of the source or drain terminals of the transistor being coupled to an electrode of a capacitor, the other source or drain terminal is coupled to a drive line (DL), which may alternatively be referred to as a source line. During operation, the DL provides current or voltage for writing (i.e., changing the polarization state of the memory cell 500) and reading (i.e., sensing the polarization state of the memory cell 500).

While the array 510 shown in FIG. 5 has four such memory cells 500, in other embodiments, the array 510 may, and typically would, include many more memory cells. Furthermore, in other embodiments, the 1T memory cells as described herein may be arranged in arrays in other manners as known in the art, all of which being within the scope of the present disclosure.

FIG. 5 illustrates that BL can be shared among multiple memory cells 500 in a column, and that WL and DL can be shared among multiple memory cells 500 in a row. As noted above, the terms “row” and “column” reflect on how individual memory cells are addressed; memory cells 500 sharing a single BL are said to be in the same column, while memory cells 500 sharing a single WL are said to be on the same row. Thus, in FIG. 5, the horizontal lines refer to columns while vertical lines refer to rows. Different instances of each line (BL, WL, and DL) are indicated in FIG. 5 with different reference numerals, e.g. BL1 and BL2 are the two different instances of the BL as described herein. The same reference numeral on the different lines WL and DL indicates that those lines are used to address/control the memory cells in a single row, e.g. WL1 and DL1 are used to address/control the memory cells 500 in row 1, and so on. Each memory cell 500 may then be addressed by using the BL corresponding to the column of the cell and by using the WL and DL corresponding to the row of the cell. For example, the memory cell 500-11 is controlled by BL1, WL1, and DL1, the memory cell 500-12 is controlled by BL1, WL2, and DL2, and so on.

### Example 1T Memory Cell With Pyroelectric Material

FIG. 6 is a cross-section of an example one-transistor memory cell 600 with a pyroelectric layer, according to some embodiments of the present disclosure. The memory cell 600 includes the channel material 202, S/D regions 204 (shown as a first S/D region 604-1, e.g., a source region, and a second S/D region 604-2, e.g., a drain region), contacts 206 to the S/D regions (shown as a first S/D contact 606-1, providing electrical contact to the first S/D region 604-1, and a second S/D contact 606-2, providing electrical contact to the second S/D region 604-2). The channel material 202, S/D regions 604, and S/D contacts 606 may be similar to any of the channel material 202, S/D regions 204, and S/D contacts 206 described with respect to FIG. 2. In this example, the S/D contact 606-1 is a back side contact, e.g., the S/D contact 606-1 is formed on an opposite side of the one-transistor memory cell 600 from the S/D contact 606-2. In other embodiments, both S/D contacts may be front side contacts, or both may be backside contacts. More generally, different transistor architectures, as described with respect to FIG. 2, may be used for the one-transistor memory cell 600.

The one-transistor memory cell 600 further includes a gate electrode 210, which may be similar to the gate electrode 210 described with respect to FIG. 2. Unlike the transistor 110 of FIG. 2, instead of the gate dielectric 212, the one-transistor memory cell 600 has a layer of the pyroelectric material 218. The pyroelectric material 218 stores a state of the one-transistor memory cell 600 within the transistor itself. As noted above, the pyroelectric material 218 may exhibit, at different times, two different polarization states, e.g., depending on electric field applied to the pyroelectric material 218 within the one-transistor memory cell 600. A current polarization state may be detected through a change in threshold voltage, or a change in resistance, of the transistor. As described with respect to FIG. 2, the pyroelectric material may have one of two different crystal configurations (orthorhombic or tetragonal), depending on temperature. The crystal configuration may alter the threshold voltages associated with the two respective memory states.

The pyroelectric material 218 may have a thickness 620, i.e., a distance between the gate electrode 210 and the channel material 202, that is at least 5 nanometers (nm), at least 10 nm, or at least 20 nm. The thickness 620 of the pyroelectric material 218 may be, for example, between 5 nm and 50 nm, between 5 nm and 30 nm, between 10 nm and 20 nm, or within some other range. In some embodiments, a layer of gate dielectric 212 may also be included in the 600, e.g., between the pyroelectric material 218 and the gate electrode 210, and/or between the pyroelectric material 218 and the channel material 202.

As illustrated in FIG. 5, a BL to transfer the memory state may be coupled to the S/D region 604-2. Such a bitline can be connected to a sense amplifier and a bitline driver which may, e.g., be provided in a memory peripheral circuit associated with a memory array in which the memory cell 600 may be included. A WL may be coupled to the gate terminal of the transistor, e.g., coupled to the gate electrode 210, to supply a gate signal. The other S/D region 604-1 may be coupled to a DL or source line, as shown in FIG. 5.

### Example 1T-nC Memory Cells With Pyroelectric Material

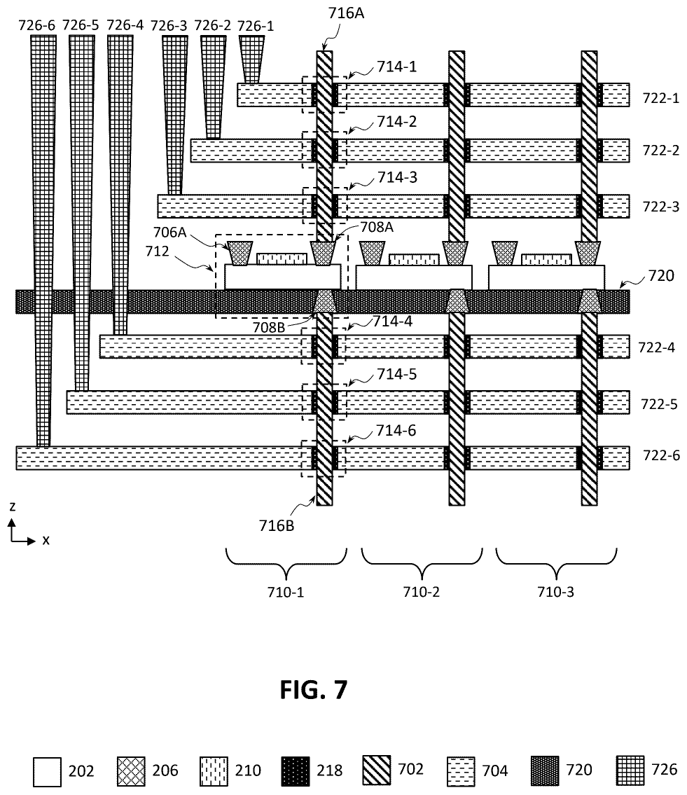

FIG. 7 is a cross-section of an example set of memory cells with one transistor coupled to multiple capacitors, with a pyroelectric layer in each capacitor, according to some embodiments of the present disclosure. FIG. 7 illustrates three memory units 710-1, 710-2, and 710-3. Each memory unit 710 includes one access transistor 712 and six capacitors 714 coupled to the access transistor 712. The access transistor 712 and six capacitors 714-1 through 714-6 of the memory unit 710-1 are labeled in FIG. 7. The other memory units 710-2 and 710-3 have a similar structure. The access transistors 712 are arranged in a device layer. The capacitors 714 are arranged in multiple capacitor layers, as described below.

The access transistor 712 includes channel material 202, a gate electrode 210, and S/D contacts 206. These may be similar to the channel material 202, a gate electrode 210, and S/D contacts 206 described with respect to FIG. 2. The access transistor 712 is formed over the support structure 720, which may be similar to the support structures or substrates described with respect to FIG. 2. A gate dielectric (e.g., the gate dielectric 212) may be between the channel material 202 and gate electrode 210, as shown in FIG. 2.

The gate electrode 210 may be coupled to a WL, not specifically shown in FIG. 7, e.g., as described in relation to FIGS. 1 and 2. S/D regions (e.g., similar to the S/D regions 204) may be formed in the channel material 202 and coupled to respective S/D contacts 206. In this example, the access transistor 712 includes three S/D contacts 206. A first S/D contact 706 (e.g., a source contact) on the left of the gate electrode 210 may be coupled to a BL, similar to the S/D contact 206-2 of FIG. 2. The access transistor 712 further includes two S/D contacts 708A and 708B (e.g., two drain contacts) to the right of the gate electrode 210, where the S/D contact 708A is on a front side of the access transistor 712 and the other S/D contact 708B is on a back side of the access transistor 712.

The first drain contact 708A is coupled to the conductive node 716A that extends over a front side of the access transistor 712, and the second drain contact 708B is coupled to the conductive node 716B that extends below the back side of the access transistor 712. Each of the respective conductive nodes 716A and 716B is coupled to a respective subset of the capacitors. In this example, the conductive node 716A is coupled to the capacitors 714-1, 714-2, and 714-3, while the conductive node 716B is coupled to the capacitors 714-4, 714-5, and 714-6. While each conductive node 716A and 716B is coupled to three capacitors 714, in other embodiments, each conductive node 716A and 716B may be coupled to one, two, three, four, five, or more capacitors. In addition, the conductive nodes 716A and 716B may be coupled to different numbers of capacitors, e.g., the conductive node 716A may be coupled to two capacitors, while the conductive node 716B is coupled to three capacitors.

The conductive nodes 716 include a conductive material 702 that couples an S/D contact to a set of capacitors 714. In this example, the conductive nodes 716 also form one electrode of each of the capacitors 714 coupled to the conductive node. The conductive nodes 716 are formed from a conductive material 702, e.g., any of the materials described with respect to the capacitor electrode 216. The conductive layers 722 form a second electrode of each of the capacitors 714. For example, for capacitor 714-1, the conductive node 716A forms a first electrode, and the conductive layer 722-1 forms a second electrode. The conductive layers 722 are formed from a conductive material 704, e.g., any of the materials described with respect to the capacitor electrode 216. In some embodiments, the conductive material 702 of the conductive nodes 716 and conductive material 704 of the conductive layers 722 include the same material.

Within each capacitors 714, the pyroelectric material 218 is between the conductive node 716 and conductive layers 722. For example, in the capacitor 714-1, the pyroelectric material 218 is between the conductive node 716A and the conductive layer 722-1. The conductive nodes 716 and conductive layers 722 thus form a pair of conductive layers, also referred to as a pair of metal layers, around the pyroelectric material 218. The pyroelectric material 218 may include any of the pyroelectric materials described above. Thus, each of the capacitors 714 is the storage element of a pyroelectric memory cell, having the temperature-dependent crystal characteristics described above.

Each of the conductive layers 722-1 through 722-6 may be considered to be in a separate capacitor layer of the device illustrated in FIG. 7. The conductive layers 722-1 through 722-6 may also be referred to as platelines. Conductive layers 722-1 through 722-3 are in respective capacitor layers over the support structure 720 and the access transistors 712. Conductive layers 722-4 through 722-6 are in respective capacitor layers under the support structure 720 and under the access transistors 712. The capacitors 714-1 through 714-3 are positioned over the access transistor 712, and capacitors 714-4 through 714-6 are positioned under the access transistor 712.

In this example, each conductive layer 722-1 through 722-6 is coupled to a respective conductive via 726-1 through 726-6. Each of the conductive vias 726 extends down from a front side of the device. The conductive via 726-1 is coupled to the top conductive layer 722-1 (or plateline) on the highest capacitor layer, and each subsequent conductive via 726-2 through 726-6 is coupled to the next conductive layer 722 (or plateline) in a lower capacitor layer. For example, the conductive via 726-2 extends through the capacitor layer that includes the conductive layer 722-1, but is not coupled to the conductive layer 722-1. The conductive via 726-6 extends through the capacitor layers of each of the conductive layers 722-1 through 722-5 to connect to the conductive layer 722-6. The conductive vias 726-4 through 726-6 also extend through the support structure 720 and through a device layer that includes the access transistors 712.

### Example Devices

The memory cells with pyroelectric layers disclosed herein may be included in any suitable electronic device. FIGS. 6-9 illustrate various examples of apparatuses that may include the one or more capacitors disclosed herein.

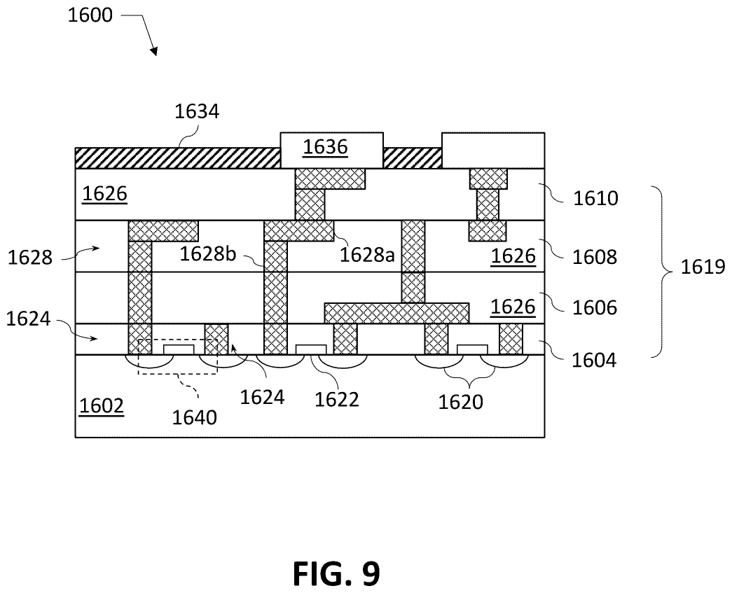

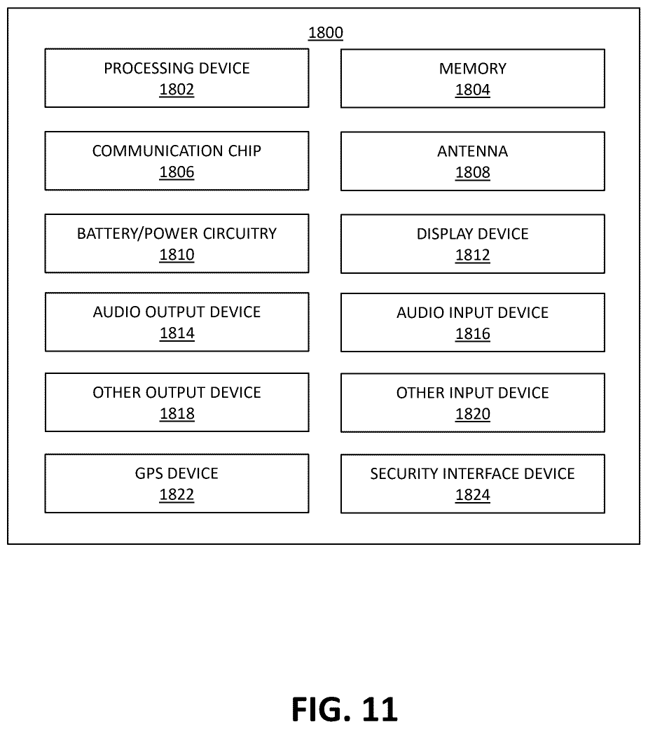

FIGS. 8A and 8B are top views of a wafer and dies that include one or more IC structures including one or more memory cells with pyroelectric layers in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1-5, or any further embodiments of the IC structures described herein). After the fabrication of the semiconductor product is complete (e.g., after manufacture of one or more IC structures with one or more of the transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more of the transistors as disclosed herein may take the form of the wafer 1500 (e.g., not singulated) or the form of the die 1502 (e.g., singulated). The die 1502 may include one or more transistors (e.g., one or more of the transistors 1640 of FIG. 9, discussed below) and/or supporting circuitry to route electrical signals to the transistors, as well as any other IC components (e.g., one or more of the non-planar transistors described herein). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 11) or other logic that is configured to store information in the memory devices or execute instructions stored in the memory array.

FIG. 9 is a cross-sectional side view of an IC device 1600 that may include one or more memory cells with pyroelectric layers in accordance with any of the embodiments disclosed herein. The IC device 1600 may be formed on a substrate 1602 (e.g., the wafer 1500 of FIG. 8A) and may be included in a die (e.g., the die 1502 of FIG. 8B). The substrate 1602 may be any substrate as described herein. The substrate 1602 may be part of a singulated die (e.g., the dies 1502 of FIG. 8B) or a wafer (e.g., the wafer 1500 of FIG. 8A).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more memory cells with pyroelectric layers at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 9 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 9). Although a particular number of interconnect layers 1606-1610 is depicted in FIG. 9, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 9. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 9. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

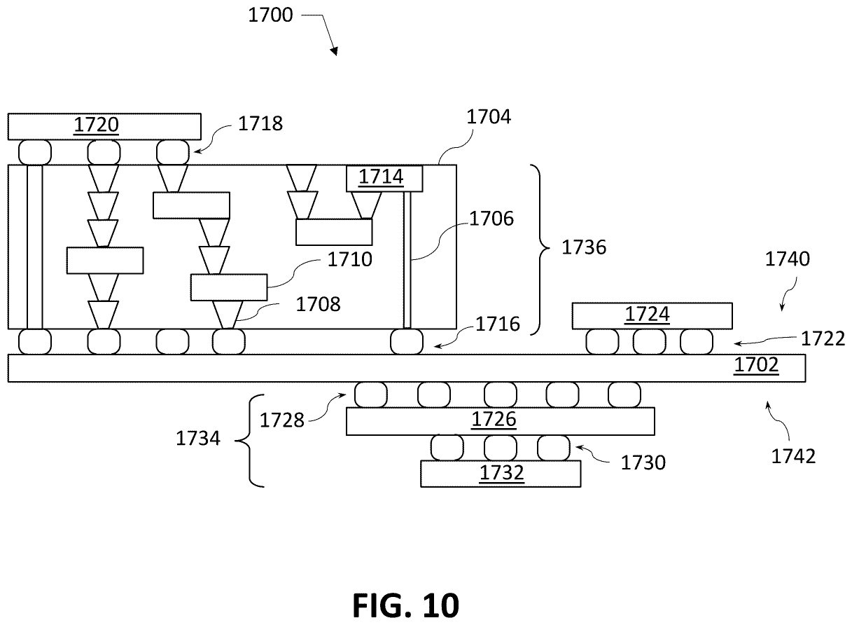

FIG. 10 is a cross-sectional side view of an IC device assembly 1700 that may include components having or being associated with (e.g., being electrically connected by means of) one or more memory cells with pyroelectric layers in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the non-planar transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 10 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 10), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 10, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 8B), an IC device (e.g., the IC device 1600 of FIG. 9), or any other suitable component. In some embodiments, the IC package 1720 may include one or more memory cells with pyroelectric layers, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 10, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 10 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 11 is a block diagram of an example computing device 1800 that may include one or more memory cells with pyroelectric layers in accordance with any of the embodiments disclosed herein. For example, any suitable ones of the components of the computing device 1800 may include a die (e.g., the die 1502 (FIG. 8B)) having one or more memory cells with pyroelectric layers. Any one or more of the components of the computing device 1800 may include, or be included in, an IC device 1600 (FIG. 9). Any one or more of the components of the computing device 1800 may include, or be included in, an IC device assembly 1700 (FIG. 10).

A number of components are illustrated in FIG. 11 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 11, but the computing device 1800 may include interface circuitry for coupling to the one or more components. For example, the computing device 1800 may not include a display device 1812, but may include display device interface circuitry (e.g., a connector and driver circuitry) to which a display device 1812 may be coupled. In another set of examples, the computing device 1800 may not include an audio input device 1816 or an audio output device 1814, but may include audio input or output device interface circuitry (e.g., connectors and supporting circuitry) to which an audio input device 1816 or audio output device 1814 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the computing device 1800 may include a communication chip 1806 (e.g., one or more communication chips). For example, the communication chip 1806 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 1402.11 family), IEEE 1402.18 standards (e.g., IEEE 1402.18-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.18 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.18 standards. The communication chip 1806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The computing device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as GPS, EDGE, GPRS, CDMA, WiMAX, LTE, EV-DO, or others. In some embodiments, a first communication chip 1806 may be dedicated to wireless communications, and a second communication chip 1806 may be dedicated to wired communications.

The computing device 1800 may include a battery/power circuitry 1810. The battery/power circuitry 1810 may include one or more energy storage devices (e.g., batteries or capacitors) and/or circuitry for coupling components of the computing device 1800 to an energy source separate from the computing device 1800 (e.g., AC line power).

The computing device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1814 (or corresponding interface circuitry, as discussed above). The audio output device 1814 may include any device that generates an audible indicator, such as speakers, headsets, or earbuds, for example.

The computing device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The computing device 1800 may include another output device 1818 (or corresponding interface circuitry, as discussed above). Examples of the other output device 1818 may include an audio codec, a video codec, a printer, a wired or wireless transmitter for providing information to other devices, or an additional storage device.

The computing device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may include a global positioning system (GPS) device 1822 (or corresponding interface circuitry, as discussed above). The GPS device 1822 may be in communication with a satellite-based system and may receive a location of the computing device 1800, as known in the art.

The computing device 1800 may include a security interface device 1824. The security interface device 1824 may include any device that provides security features for the computing device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### SELECT EXAMPLES

The following paragraphs provide various examples of the embodiments disclosed herein.

Example 1 provides a device including an access transistor; and a capacitor coupled to the access transistor, the capacitor including a pyroelectric layer between a pair of metal layers, the pyroelectric layer including a pyroelectric material.

Example 2 provides the device of example 1, where, at a first temperature, the pyroelectric material is arranged in an orthorhombic configuration.

Example 3 provides the device of example 2, where, at a second temperature, the pyroelectric material is arranged in a tetragonal configuration, the first temperature greater than the second temperature.

Example 4 provides the device of any of examples 1-3, where the pyroelectric material can exhibit two polarization states.

Example 5 provides the device of example 4, where applying an electric field to the pyroelectric layer changes the polarization state of the pyroelectric layer.

Example 6 provides the device of any of examples 1-5, where the capacitor is a first capacitor, the device further including a second capacitor coupled to the access transistor, the second transistor including a second pyroelectric layer including the pyroelectric material.

Example 7 provides the device of any of examples 1-6, where the pyroelectric material includes nitrogen and one of aluminum, zirconium, gallium, indium, and hafnium.

Example 8 provides the device of any of examples 1-6, where the pyroelectric material is a dielectric material including oxygen and a metal.

Example 9 provides the device of example 8, where the metal is one of lead, zirconium, barium, hafnium, and tantalum.

Example 10 provides the device of example 8 or 9, where the pyroelectric material further includes a dopant, where the dopant is one of zirconium, hafnium, silicon, aluminum, tantalum, germanium, gallium, and titanium.

Example 11 provides an integrated circuit (IC) device including a first memory device including a first semiconductor region coupled to a first bit line; a first conductive region coupled to a word line; and a first pyroelectric layer between the first semiconductor region and the first conductive region, the first pyroelectric layer including a pyroelectric material; and a second memory device including a second semiconductor region coupled to a second bit line; a second conductive region coupled to the word line; and a second pyroelectric layer between the second semiconductor region and the second conductive region, the second pyroelectric layer including the pyroelectric material.

Example 12 provides the IC device of example 11, where, at a first temperature, the pyroelectric material in the first pyroelectric layer and the second pyroelectric layer is arranged in an orthorhombic configuration.

Example 13 provides the IC device of example 12, where, at a second temperature, the pyroelectric material in the first pyroelectric layer and the second pyroelectric layer is arranged in a tetragonal configuration, the first temperature greater than the second temperature.

Example 14 provides the IC device of any of examples 11-13, where the pyroelectric material can exhibit two polarization states.

Example 15 provides an assembly including a computing portion; and a memory portion including a plurality of memory cells, one of the memory cells including a pyroelectric material, where a crystal structure of the pyroelectric material is altered by heat emitted by the computing portion.

Example 16 provides the assembly of example 15, where the computing portion is on a first die, and the memory portion is on a second die.

Example 17 provides the assembly of example 15, where the computing portion is on a first region of a die, and the memory portion is on a second region of the die.

Example 18 provides the assembly of any of examples 15-17, where, in a first temperature range, the crystal structure of the pyroelectric material has an orthorhombic configuration, and in a second temperature range, the crystal structure of the pyroelectric material has a tetragonal configuration.

Example 19 provides the assembly of example 18, where the memory portion of the assembly generates less heat during operation in the orthorhombic configuration than in the tetragonal configuration.

Example 20 provides the assembly of example 18 or 19, where the first temperature range is above the second temperature range.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. A device comprising:
an access transistor; and
a capacitor coupled to the access transistor, the capacitor comprising a pyroelectric layer between a pair of metal layers, the pyroelectric layer comprising a pyroelectric material.

2. The device of claim 1, wherein, at a first temperature, the pyroelectric material is arranged in an orthorhombic configuration.

3. The device of claim 2, wherein, at a second temperature, the pyroelectric material is arranged in a tetragonal configuration, and the first temperature is greater than the second temperature.

4. The device of claim 1, wherein the pyroelectric material can exhibit two polarization states.

5. The device of claim 4, wherein applying an electric field to the pyroelectric layer changes the polarization state of the pyroelectric layer.

6. The device of claim 1, wherein the capacitor is a first capacitor, the device further comprising a second capacitor coupled to the access transistor, the second transistor comprising a second pyroelectric layer comprising the pyroelectric material.

7. The device of claim 1, wherein the pyroelectric material comprises nitrogen and one of aluminum, zirconium, gallium, indium, and hafnium.

8. The device of claim 1, wherein the pyroelectric material is a dielectric material comprising oxygen and a metal.

9. The device of claim 8, wherein the metal is one of lead, zirconium, barium, hafnium, and tantalum.

10. The device of claim 8, wherein the pyroelectric material further includes a dopant, wherein the dopant is one of zirconium, hafnium, silicon, aluminum, tantalum, germanium, gallium, and titanium.

11. An integrated circuit (IC) device comprising:
a first memory device comprising:
a first semiconductor region coupled to a first bit line;
a first conductive region coupled to a word line; and
a first pyroelectric layer between the first semiconductor region and the first conductive region, the first pyroelectric layer comprising a pyroelectric material; and
a second memory device comprising:
a second semiconductor region coupled to a second bit line;
a second conductive region coupled to the word line; and
a second pyroelectric layer between the second semiconductor region and the second conductive region, the second pyroelectric layer comprising the pyroelectric material.

12. The IC device of claim 11, wherein, at a first temperature, the pyroelectric material in the first pyroelectric layer and the second pyroelectric layer is arranged in an orthorhombic configuration.

13. The IC device of claim 12, wherein, at a second temperature, the pyroelectric material in the first pyroelectric layer and the second pyroelectric layer is arranged in a tetragonal configuration, the first temperature greater than the second temperature.

14. The IC device of claim 11, wherein the pyroelectric material can exhibit two polarization states.

15. An assembly comprising:
a computing portion; and
a memory portion comprising a plurality of memory cells, one of the memory cells comprising a pyroelectric material, wherein a crystal structure of the pyroelectric material is altered by heat generated by the computing portion.

16. The assembly of claim 15, wherein the computing portion is on a first die, and the memory portion is on a second die.

17. The assembly of claim 15, wherein the computing portion is on a first region of a die, and the memory portion is on a second region of the die.

18. The assembly of claim 15, wherein, in a first temperature range, the crystal structure of the pyroelectric material has an orthorhombic configuration, and in a second temperature range, the crystal structure of the pyroelectric material has a tetragonal configuration.

19. The assembly of claim 18, wherein the memory portion of the assembly generates less heat during operation in the orthorhombic configuration than in the tetragonal configuration.

20. The assembly of claim 18, wherein the first temperature range is above the second temperature range.
